(19) United States
(12) Patent Application Publication
(10) Pub. No.: US 2015/0064857 A1
(43) Pub. Date: Mar. 5, 2015

(54) MASK FOR EXPOSURE, METHOD OF FABRICATING THE SAME, AND METHOD OF FABRICATING DISPLAY PANEL USING THE MASK

(71) Applicant: SAMSUNG DISPLAY CO., LTD., Yongin-City (KR)

(72) Inventors: MIN KANG, Seoul (KR); Hyunjoo Lee, Seoul (KR); Bong-Yeon Kim, Seoul (KR); DongEon Lee, Seoul (KR); Yong Son, Gyeonggi-do (KR); Junhyuk Woo, Gyeonggi-do (KR); Jinho Ju, Seoul (KR)

(73) Assignee: SAMSUNG DISPLAY CO., LTD., Yongin-City (KR)

(21) Appl. No.: 14/224,284

(22) Filed: Mar. 25, 2014

(30) Foreign Application Priority Data
Sep. 5, 2013 (KR) 10-2013-0106791

(51) Int. Cl. G03F 1/26; H01L 21/033; H01L 27/12

(52) U.S. Cl. CPC G03F 1/26; H01L 27/1288; H01L 21/0335; H01L 21/0338
USPC 438/158; 430/5

(57) ABSTRACT

A mask for etching a target layer includes a mask substrate. A phase inversion layer is disposed to correspond to a non-etched area of a pattern target layer. The phase inversion layer is configured to generate inverted light by inverting a phase of incident light and to transmit the inverted light to the non-etched area of a pattern target layer. An inversion offset part is disposed in a center part of the phase inversion layer. The inversion offset part is configured to generate offset light causing destructive interference with the inverted light in the non-etched area and to provide the offset light to the non-etched area.

### CROSS-REFERENCE TO RELATED APPLICATIONS

This U.S. non-provisional patent application claims priority under 35 §119 to Korean Patent Application No. 10-2013-0106791, filed on Sep. 5, 2013, the disclosure of which is incorporated by reference herein in its entirety.

### TECHNICAL FIELD

The present disclosure relates to a mask, and more particularly to a mask for exposure, a method of fabricating the same, and a method of fabricating a display panel using the mask.

### DISCUSSION OF RELATED ART

Optical photolithography may form an image corresponding to a mask pattern on a photoresist, which is provided on a pattern target layer, by projecting or transmitting light through the mask pattern that is composed of optically opaque regions and optically transparent regions. The photoresist may be developed and the pattern target layer may be etched by using the developed photoresist as a mask, and a desired pattern of the pattern target layer may be formed.

The optically opaque regions of the mask pattern may generate dark regions by blocking the light. The optically transparent regions of the mask may generate bright regions by transmitting the light. When a size of the optically transparent region is small, the light transmitted through the optically transparent region may be diffracted so that a boundary of an image on the photoresist becomes unclear. The resolution of optical photolithography may be decreased and the uniformity of the fine pattern may be reduced.

### SUMMARY

The present disclosure provides a mask for exposure which may form a fine pattern with higher resolution than a resolution limit of an exposure apparatus.

Exemplary embodiments of the present inventive concept provide an exposure mask for etching a pattern target layer including a mask substrate. A phase inversion layer disposed to correspond to a non-etched area of a pattern target layer. The phase inversion layer is configured to generate inverted light by inverting a phase of incident light and to transmit the inverted light to the non-etched area of the pattern target layer. An inversion offset part is disposed in a center part of the phase inversion layer. The inversion offset part is configured to generate offset light causing destructive interference with the inverted light in the non-etched area and to provide the offset light to the non-etched area.

According to an exemplary embodiment of the present inventive concept, the inversion offset part may include a slit disposed in the phase inversion layer. The offset light may have a non-inverted phase that is transmitted through the slit.

According to an exemplary embodiment of the present inventive concept, the inversion offset part may include a phase reinversion layer disposed on the phase inversion layer. The offset light may have a phase that is inverse to a phase of the inverted light that is transmitted through the phase inversion layer.

According to an exemplary embodiment of the present inventive concept, the phase reinversion layer may include a same material as the phase inversion layer. The phase reinversion layer may have a same thickness as the phase inversion layer.

According to an exemplary embodiment of the present inventive concept, a width of the inversion offset part may be in a range of about 0.1 μm to about 1 μm.

According to an exemplary embodiment of the present inventive concept, when a pitch is defined as a sum of a width of the etched area and a width of the non-etched area, the pitch may be in a range of about 2 μm to about 20 μm.

According to an exemplary embodiment of the present inventive concept, a wavelength of the light transmitted to the mask substrate may be in a range of about 300 nm to about 450 nm.

According to an exemplary embodiment of the present inventive concept, a plurality of inversion offset parts may be disposed in the non-etched area.

According to exemplary embodiments of the present inventive concept, a method of fabricating a mask for exposure for etching a pattern target includes providing a phase conversion material configured to shift a phase of light transmitted to a mask substrate. The method may include forming a phase inversion layer on the mask substrate. The phase inversion layer may generate inverted light by inverting a phase of the transmitted light to provide the transmitted light to a non-etched area of a pattern target layer by etching the phase conversion material. The method may include forming an inversion offset part. The inversion offset part may generate offset light causing destructive interference with the inverted light in a center part of a non-etched area of the pattern target layer and provides the offset light to a center portion of the non-etched area.

According to an exemplary embodiment of the present inventive concept, the forming of the phase inversion layer and the inversion offset part may include forming a slit that generates the offset light having a non-inverted phase by etching the phase inversion layer on the center part of the non-etched area.

According to an exemplary embodiment of the present inventive concept, the forming of the phase inversion layer and the inversion offset part may include forming a phase reinversion layer that generates the offset light having a phase that is inverse to a phase of the inverted light on the center part of the non-etched area.

According to an exemplary embodiment of the present inventive concept, the forming of the phase inversion layer and the inversion offset part may include etching a portion of the phase conversion material.

According to an exemplary embodiment of the present inventive concept, a method of fabricating a display panel includes forming a base substrate. The method includes forming a thin film transistor on the base substrate. The method includes forming a pixel electrode electrically connected to the thin film transistor on the base substrate. The method includes forming a micro pattern on the pixel electrode using a mask for exposure. An etched area and a non-etched area, which correspond to the micro pattern, are defined in the pixel electrode. The mask for exposure includes a mask substrate. A phase inversion layer is disposed to correspond to the non-etched area. The phase inversion layer generates inverted light by inverting a phase of incident light and to provide the inverted light to the non-etched area of the pattern target layer. An inversion offset part is disposed in a center part of the phase inversion layer. The inversion offset part is configured to offset light causing destructive interference with the inverted light in the non-etched area and to provide the offset light to the non-etched area.

According to an exemplary embodiment of the present inventive concept, the inversion offset part may include a slit formed in the phase inversion layer. The offset light may have a non-inverted phase that is transmitted through the

According to an exemplary embodiment of the present inventive concept, the inversion offset part may include a phase reinversion layer formed on the phase inversion layer. The offset light may have a phase that is inverse to a phase of the inverted light that is transmitted through the phase inversion layer.

### BRIEF DESCRIPTION OF THE DRAWINGS

The above and other features of the present invention will become more apparent by describing in detail exemplary embodiments thereof, with reference to the accompanying drawings in which:

FIG. 1 is a cross-sectional view illustrating a mask for exposure according to an exemplary embodiment of the present inventive concept;

FIG. 2 is a cross-sectional view illustrating a mask for exposure, intensities of lights transmitted through the mask for exposure, and a developed photoresist layer according to exemplary embodiments of the present inventive concept;

FIG. 3 is a cross-sectional view illustrating a mask for exposure according to an exemplary embodiment of the present inventive concept;

FIG. 4 is a cross-sectional view illustrating a mask for exposure according to an exemplary embodiment of the present inventive concept;

FIG. 5 is a cross-sectional view illustrating a mask for exposure according to an exemplary embodiment of the present inventive concept;

FIGS. 6A and 6B are cross-sectional views sequentially illustrating a process of fabricating a mask for exposure according to an exemplary embodiment of the present inventive concept;

FIGS. 7A and 7B are cross-sectional views sequentially illustrating a process of fabricating a mask for exposure according to an exemplary embodiment of the present inventive concept; and

FIG. 8 is a cross-sectional view illustrating a display panel fabricated by a method of fabricating a display panel according to an exemplary embodiment of the present inventive concept.

### DETAILED DESCRIPTION OF THE EMBODIMENTS

While the present inventive concept is amenable to various modifications and alternative forms, specific embodiments have been shown by way of example in the drawings and are described in detail below. The intention, however, is not to limit the present inventive concept to the particular exemplary embodiments described. The present inventive concept is intended to cover all modifications, equivalents, and alternatives of the exemplary embodiments disclosed herein.

In the drawings, like reference numerals may refer to like elements throughout. Sizes of elements in the drawings may be exaggerated for clarity of illustration. Terms such as “first” and “second” may be used to describe various components, however, the components are not limited to these terms. These terms might be used to differentiate one component from another one. For example, a component referred to as a first component in an exemplary embodiment may be referred to as a second component in another embodiment. The terms of a singular form may include plural forms.

When an element such as a layer, film, region, or substrate is referred to as being “on” another element, it may be directly on the other element or intervening elements may be present. When an element such as a layer, film, region, or substrate is referred to as being “under” another element, it may be directly under the other element or intervening elements may be present.

Hereinafter, exemplary embodiments of the present inventive concept will be described in detail with reference to the accompanying drawings.

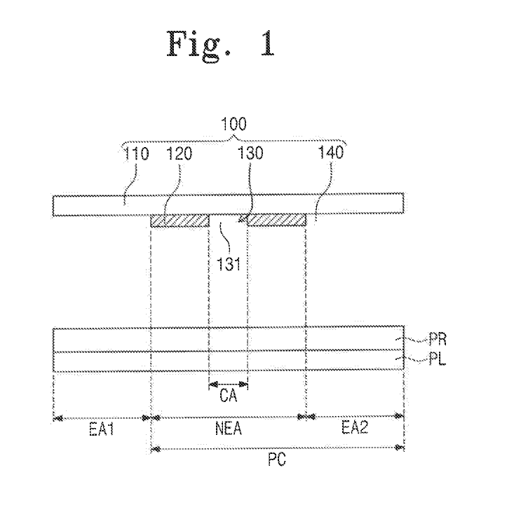

FIG. 1 is a cross-sectional view illustrating a mask for exposure according to an exemplary embodiment of the present inventive concept.

Referring to FIG. 1, a mask for exposure 100 includes a mask substrate 110, a phase inversion layer 120, an inversion offset part 130, and openings 140. In a photolithography process, a photoresist layer PR may be exposed and developed by using the mask for exposure 100. A predetermined pattern may be formed on a pattern target layer PL by etching the pattern target layer PL using the developed photoresist layer PR.

The mask for exposure 100 may be disposed between an exposure apparatus (not shown) and the pattern target layer PL, for example, during the photolithography process.

The exposure apparatus may be disposed above the mask for exposure 100. The exposure apparatus may emit light onto the mask for exposure 100. A wavelength of the light emitted from the exposure apparatus, for example, may be in a range of from about 300 nm to about 450 nm. According to an exemplary embodiment of the present inventive concept, the light emitted from the exposure apparatus may include three or more lights having three different wavelengths. For example, the three lights may be G-line light having a wavelength of about 435 nm, H-line light having a wavelength of about 405 nm, and I-line light having a wavelength of about 365 nm, respectively.

The pattern target layer PL may be disposed under the mask for exposure 100 and may include first and second etched areas EA1 and EA2, and a non-etched area NEA. The NEA may be disposed between the etched areas EA1 and EA2. The pattern target layer PL may be etched so that a predetermined pattern is formed by a photolithography process using the mask for exposure 100. For example, the pattern target layer PL in the etched areas EA1 and EA2 might be etched and the pattern target layer PL in the non-etched area NRA might not be etched.

According to an exemplary embodiment of the present inventive concept, only the single non-etched area NEA disposed between the etched areas EA1 and EA2 is defined. However, embodiments of the present inventive concept are not limited thereto, and the etched areas EA1 and EA2 and the non-etched area NEA may be defined by being variously modified according to the shape of a pattern. For example, the etched areas EA1 and EA2 and the non-etched area NEA may be provided in plurality and may be alternatingly disposed.

A pitch PC denotes a sum of a width of the single etched area EA1 and a width of the single non-etched area NEA. A pattern formed on the pattern target layer PL may becomes fine when the pitch PC is relatively small. Hereinafter, the expression “fine pattern” may denote a 2-dimensional or 3-dimensional shape, arrangement, and structure having a size of a few tens of nanometers to a few tens of micrometers. A value of the pitch, for example, may be in a range of about 2 μm to about 20 μm. However, the value of the pitch is not limited thereto and the value of the pitch may be variously changed according to a desired pattern.

The photoresist layer PR may be provided on the pattern target layer PL. The photoresist layer PR may be formed of a photoresist material which includes a photosensitive material. For example, when light having an intensity above a predetermined threshold is incident on the photoresist layer PR, the photoresist layer PR may be exposed. The exposure may denote that a portion of the photoresist layer PR irradiated with light has solubility with respect to a photoresist developer. For example, when light having an intensity below a predetermined threshold is incident on the photoresist layer PR, since physical properties of the photoresist layer PR are not changed, the photoresist layer PR need not be exposed, and the photoresist layer PR might not be dissolved by the photoresist developer.

The mask substrate 110 may include a transparent material, such as, for example, quartz. Most of the light emitted to the mask substrate 110 from the exposure apparatus during the photolithography process may be transmitted through the mask substrate 110.

The openings 140 may be disposed on the mask substrate 110 to correspond to the etched areas EA1 and EA2. The light emitted to the mask substrate 110 may arrive on the photoresist layer PR by passing through the openings 140. Hereinafter, the light passing through the openings 140 may be defined as phase non-inverted, and the light transmitted through the openings 140 may be referred to as non-inverted light.

The phase inversion layer 120 may be disposed on the mask substrate 110. The phase inversion layer 120 may correspond to the non-etched area NEA. The phase inversion layer 120 may generate inverted light having a phase different from the phase of the non-inverted light. For example, a phase difference between the non-inverted light and the light transmitted through the phase inversion layer 120 may be generated by generating a path difference between the non-inverted light and the light transmitted through the phase inversion layer 120. For example, when an optical path of the light transmitted through the phase inversion layer 120 is controlled by adjusting a thickness of the phase inversion layer 120, inverted light having a phase inverted based on the phase of the non-inverted light may be generated. The inverted light may arrive at the photoresist layer PR after passing through the phase inversion layer 120.

The phase inversion layer 120 may include a phase conversion material that shifts a phase of light. The phase inversion layer 120 may absorb most of the incident light and transmit the remaining part of the light by delaying the phase thereof. A transmittance of the phase inversion layer 120 may be in a range of about 4% to about 15%. The phase inversion layer 120, for example, may include a material, such as chromium oxide (CrOx) or molybdenum suicide.

The inversion offset part 130 may be formed in a center part CA of the phase inversion layer 120. The inversion offset part 130 may generate offset light. The offset light may be a phase-inverted light based on the inverted light. The phase of the offset light may be non-inverted and may be the same as that of the non-inverted light. The offset light may arrive at the photoresist layer PR after passing through the inversion offset part 130.

For example, the inversion offset part 130 may be a slit 131 formed in the center part CA of the phase inversion layer 120. The slit 131 may be formed by opening the phase inversion layer 120 of the center part CA. For example, when the phase inversion layer 120 of the center part CA, in which the slit 131 is formed, is opened, the light emitted to the mask substrate 110 may be transmitted without a phase delay. The offset light transmitted through the slit 131 may have the same phase as the non-inverted light.

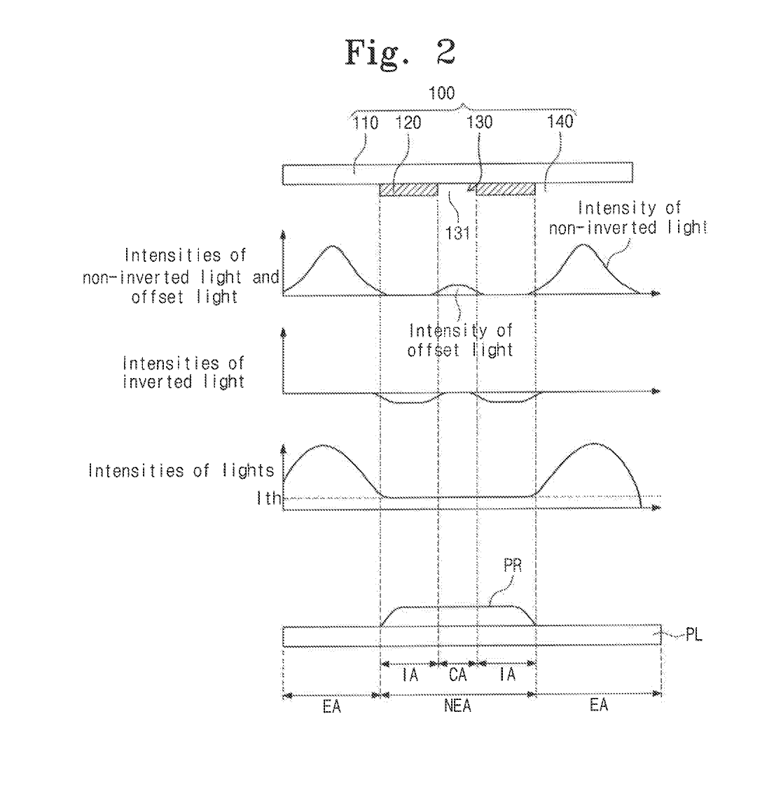

The phase inversion layer 120 might be provided only on inversion areas IA (see FIG. 2, for example) which may be the remaining areas excluding the center part CA from the area corresponding to the non-etched area NEA of the phase inversion layer 120.

A width of the slit 131, for example, may be in a range of about 0.1 μm to about 1 μm. However, the width of the slit 131 is not limited thereto, and the width of the slit 131 may be changed to any desired width.

According to an exemplary embodiment of the present inventive concept, a slit 131 may be formed in plurality as illustrated in FIG. 4. Referring to FIG. 4, the slit 131 may include a first slit 131a and a second slit 131b (see FIG. 4, for example) that may be formed in the non-etched area NEA. The slits 131 may be spaced apart from each other by a predetermined spacing along a first direction.

FIG. 2 is a cross-sectional view illustrating a mask for exposure, intensities of lights transmitted through the mask for exposure, and a developed photoresist layer according to exemplary embodiments of the present inventive concept. Descriptions regarding reference numerals that are similar to those of FIG. 1 may be omitted.

Referring to FIG. 2, the mask for exposure 100 according to an exemplary embodiment of the present inventive concept may form a photoresist layer PR having a uniform thickness in the non-etched area NBA.

Intensities of non-inverted light and offset light in FIG. 2 may represent the intensities of the non-inverted light and offset light transmitted onto the photoresist layer PR among the lights transmitted through the mask for exposure 100.

The non-inverted light transmitted through the opening 140 may be diffracted. The non-inverted light transmitted through the opening 140 may be transmitted onto the photoresist layer PR. A part of the non-inverted light may be diffracted and may be transmitted to the etched area EA and/or the non-etched area NBA. The etched area EA may be adjacent to the non-etched area NEA. The intensity of the non-inverted light may gradually decrease with increasing distance from the center of the etched area EA.

The offset light transmitted through the slit 131 of the inversion offset part 130 may be diffracted and may be transmitted onto the photoresist layer PR. The offset light transmitted through the slit 131 may be diffracted and may arrive in an area corresponding to the center part CA and/or the non-etched area NEA. The etched area EA may be adjacent to the non-etched area NEA. The intensity of the offset light may gradually decrease with increasing distance from the center of the area corresponding to the center part CA. When the width of the slit 131 is smaller than the opening 140, the intensity of the offset light may be weaker than the intensity of the non-inverted light.

The intensity of the inverted light in FIG. 2 may represent the intensity of the inverted light transmitted onto the photoresist layer PR among the lights transmitted through the mask for exposure 100. When the inverted light has its phase inverted based on the phase of the non-inverted light, the intensity of the inverted light has a negative value. When a transmittance of the phase inversion layer 120 is relatively low, the intensity of the inverted light may be weaker than the intensity of the non-inverted light.

The inverted light transmitted through the phase inversion layer 120 may be diffracted and may be transmitted onto the photoresist layer PR. The inverted light may be diffracted and may be transmitted to the inversion areas IA and/or the center part CA and/or the etched areas EA. The center part CA and/or the etched areas EA may be adjacent to the inversion areas IA. The intensity of the inverted light may gradually decrease with increasing distance from the center of the area corresponding to the inversion area IA.

The intensities of the lights in FIG. 2 may represent the intensities of the lights transmitted onto the photoresist layer PR. The offset light and the inverted light may overlap to make the intensity of the light arriving on the photoresist layer PR in the non-etched area NEA uniform.

For example, when the offset light and the inverted light in the non-etched area NEA have phases opposite to each other, the offset light and the inverted light may cause destructive interference in the non-etched area NEA. When the width of the slit 131 is controlled, the offset light and the inverted light may be allowed to interfere with each other so as to make the intensity of the light arriving on the photoresist layer PR in the non-etched area NEA uniform. For example, in the case that the pitch PC is about 8 μm, the intensity of the light in the non-etched area NEA may become uniform when the width of the slit 131 (e.g., a width of the center part CA) is about 0.8 μm.

For example, when the light arriving in the non-etched area NEA has an intensity above a threshold Iₜₕ and the intensity of the light is uniform, the photoresist layer PR may be uniformly exposed. For example, when the intensity of the light in the non-etched area NEA is weaker than the intensity of the light in the etched area EA, only an upper portion of the photoresist layer PR with a constant depth in a thickness direction from a surface of the photoresist layer PR might be exposed.

When the photoresist layer PR is developed, only the upper portion of the photoresist layer PR with the constant depth in the thickness direction from the surface of the photoresist layer PR might be developed. The photoresist layer PR may have a uniform thickness after the development process.

For example, when the non-inverted light arriving in the etched area EA has an intensity above the threshold Iₜₕ, the photoresist layer PR may be exposed. When the intensity of the light in the etched area EA is higher than the intensity of the light in the non-etched area NEA, the photoresist layer PR may be entirely exposed from the top surface thereof to the bottom surface thereof in the thickness direction.

When the photoresist layer PR is subsequently developed, the photoresist layer PR in the etched area EA may be entirely developed, and the pattern target layer PL in the etched area EA may be exposed.

For example, a mask for exposure using a phase inversion layer, inverted light transmitted through the phase inversion layer may be diffracted to have a non-uniform intensity in a non-etched area. A photoresist layer may be exposed by corresponding to the non-uniform intensity of the inverted light, and when the photoresist layer is subsequently developed, a top surface of the photoresist layer may have a groove formed in the center, e.g., side lobes. A pattern target layer may be exposed by a groove portion of the side lobes. When the pattern target layer that is exposed by the groove portion of the side lobes is etched during an etching process, an unwanted defective pattern may be formed in the non-etched area.

When a photolithography process is performed by using the mask for exposure 100 according to exemplary embodiments of the present inventive concept, the photoresist layer PR of the non-etched area NEA may be uniformly developed by the destructive interference between the offset light and the inverted light. The photoresist layer PR in the non-etched area NEA may have a uniform thickness and the formation of the side lobes in the non-etched area NEA may be prevented. When the pattern target layer PL is not exposed in the non-etched area NEA, the reliability of the photolithography process forming a micro pattern may be increased and a resolution limit of the exposure apparatus according to exemplary embodiments of the present inventive concept may be increased.

The intensity of the light in the non-etched area NEA may be below the threshold Iₜₕ, due to the destructive interference between the offset light and the inverted light in the non-etched area NEA. The photoresist layer PR in the non-etched area NEA might not be exposed. When the pattern target layer PL in the non-etched area NEA is not exposed, the resolution limit of the exposure apparatus according to exemplary embodiments of the present inventive concept may be increased. The reliability of the micro pattern formed according to the exemplary embodiments of the present inventive concept may be increased.

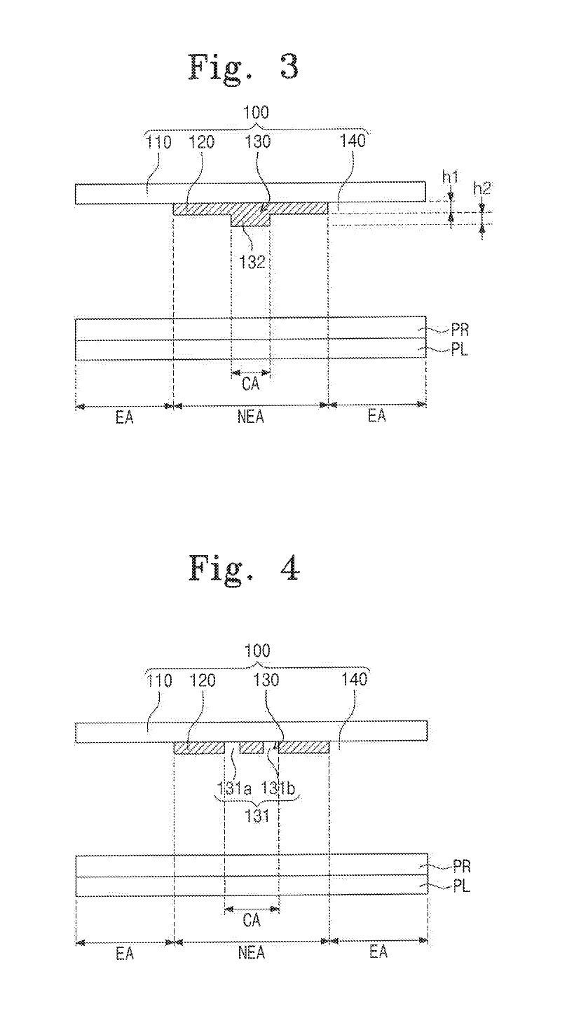

FIG. 3 is a cross-sectional view illustrating a mask for exposure according to an exemplary embodiment of the present inventive concept. Descriptions regarding reference numerals that are similar to those of FIG. 1 may be omitted.

Referring to FIG. 3, a mask for exposure 100 may include a mask substrate 110, a phase inversion layer 120, an inversion offset part 130, and openings 140.

The inversion offset part 130 may be formed in a center part CA of the phase inversion layer 120 and may generate offset light. The offset light may be phase-inverted light based on inverted light. The phase of the offset light may be the same as the phase of non-inverted light. The offset light may be transmitted onto a photoresist layer PR by transmitting the offset light through the inversion offset part 130.

The inversion offset part 130, for example, may include a phase reinversion layer 132 formed in the center part CA of the phase inversion layer 120. The phase reinversion layer 132 may be disposed on the center part CA of the phase inversion layer 120. The phase reinversion layer 132 may receive phase-inverted light transmitted through the phase inversion layer 120 in the center part CA and may generate the offset light.

The phase reinversion layer 132 may generate a phase difference due to a path difference between the inverted light and the light transmitted through the phase reinversion layer 132. When an optical path of the light transmitted by the phase reinversion layer 132 is controlled by adjusting a thickness of the phase reinversion layer 132, the offset light having a phase inverted based on the phase of the inverted light may be generated.

The phase reinversion layer 132 may include a phase conversion material that shifts a phase of light. The phase reinversion layer 132, for example, may include a same material as the phase inversion layer 120. A thickness h2 of the phase reinversion layer 132 may be the same as a thickness h1 of the phase inversion layer 120.

A width of the phase reinversion layer 132, for example, may be in a range of from about 0.1 μm to about 1 μm, for example. The width of the phase reinversion layer 132 is not limited thereto, and the width of the phase reinversion layer 132 may be variously changed.

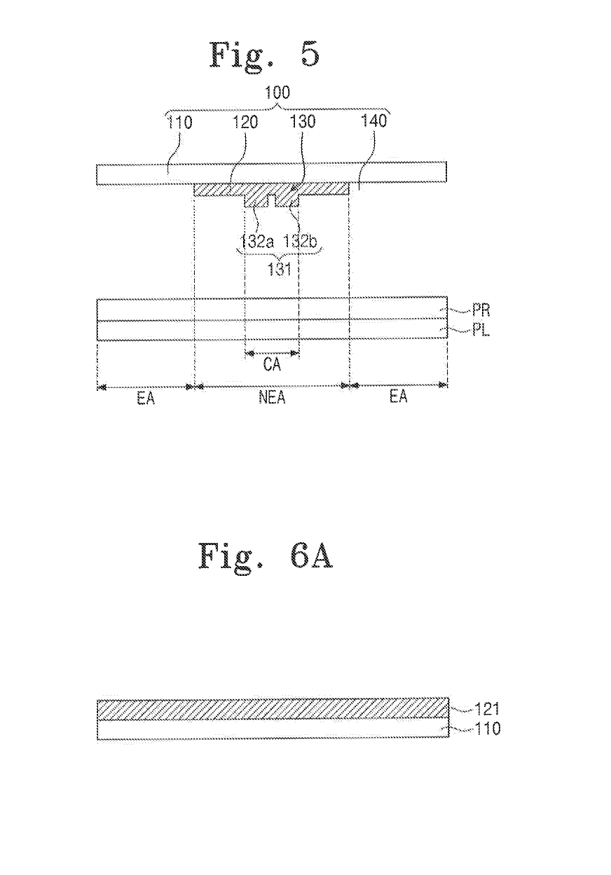

According to an exemplary embodiment of the present inventive concept, a phase reinversion layer 132 may be formed in plurality as illustrated in FIG. 5, for example. Referring to FIG. 5, the phase reinversion layer 132 may include a first phase reinversion layer 132a and a second phase reinversion layer 132b. The first phase reinversion layer 132a and a second phase reinversion layer 132b may be formed in a non-etched area NEA. The phase reinversion layers 132a and 132b may be spaced apart from each other by a predetermined spacing along a first direction.

When the phase reinversion layer 132 is included, the offset light and the inverted light may overlap to make the intensity of the light arriving on the photoresist layer PR in the non-etched area NEA uniform. The offset light and the inverted light may cause destructive interference in the non-etched area NEA. When the width of the phase reinversion layer 132 is controlled, the offset light and the inverted light may be allowed to interfere with each other so as to make the intensity of the light arriving on the photoresist layer PR in the non-etched area NEA uniform.

When the photoresist layer PR in the non-etched area NEA is uniformly developed, the photoresist layer PR in the non-etched area NEA may have a uniform thickness, and the formation of the side lobes in the non-etched area NEA may be prevented. When the pattern target layer PL in the non-etched area NEA is not exposed, the resolution limit of the exposure apparatus according to an exemplary embodiment of the present inventive concept may be increased and the reliability of the micro pattern formed according to an exemplary embodiment of the present inventive concept may be increased.

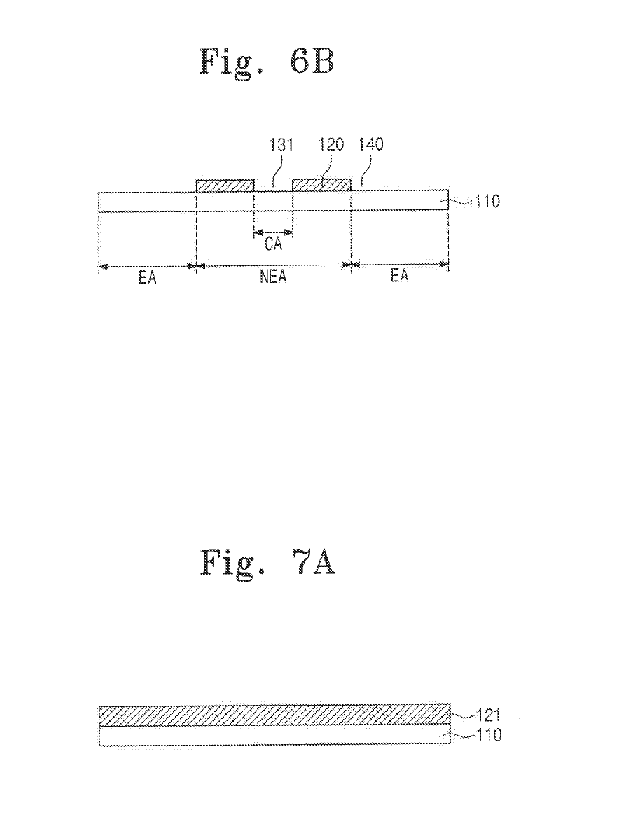

FIGS. 6A and 6B are cross-sectional views sequentially illustrating a process of fabricating a mask for exposure according to an exemplar) embodiment of the present inventive concept. Descriptions regarding reference numerals that are similar to those of FIG. 1 may be omitted.

Referring to FIG. 6A, a phase conversion material 121 may be provided on a mask substrate 110. A thickness of the phase conversion material 121 may invert a phase of light transmitted through the phase conversion material 121.

Referring to FIG. 6B, a phase inversion layer 120, openings 140, and a slit 131 may be formed on the mask substrate 110. The phase inversion layer 120, the slit 131, and the openings 140 may be formed by etching the phase conversion material 121, for example, by using a photolithography process. The openings may be formed by etching the phase conversion material 121 in etched areas EA. The slit 131 may be formed by etching the phase conversion material 121 in a center part CA.

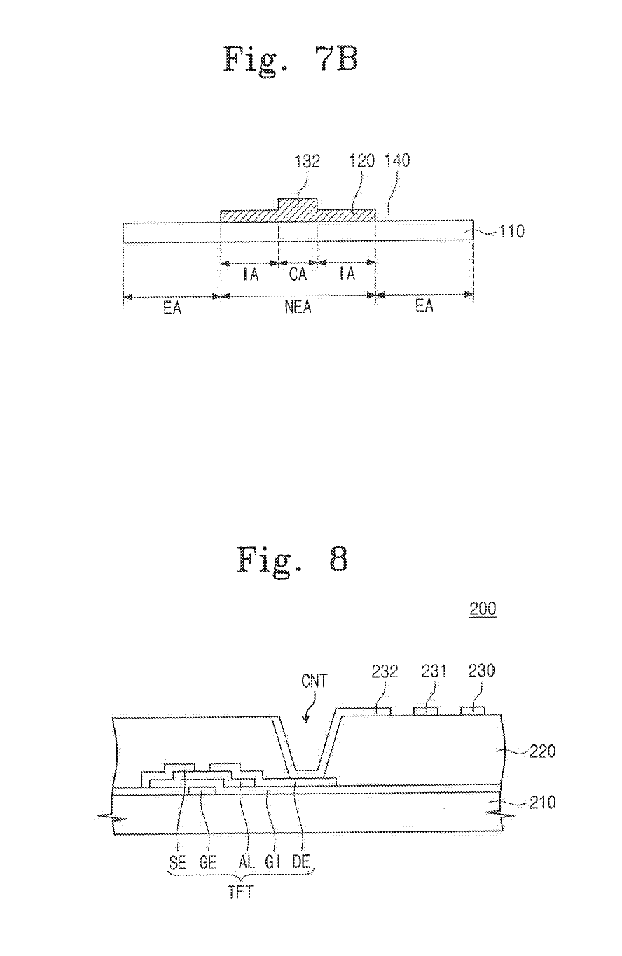

FIGS. 7A and 7B are cross-sectional views sequentially illustrating a process of fabricating a mask for exposure according to an exemplary embodiment of the present inventive concept. Descriptions regarding reference numerals that are similar to those of FIG. 3 may be omitted.

Referring to FIG. 7A, a phase conversion material 121 may be provided on a mask substrate 110. A thickness of the phase conversion material 121 may invert a phase of light transmitted through the phase conversion material 121 and then reinvert the phase of the light. The thickness of the phase conversion material 121, for example, may be twice the thickness of the phase conversion material 121 that inverts the phase of the light transmitted through the phase conversion material 121.

Referring to FIG. 7B, a phase inversion layer 120, openings 140, and a phase reinversion layer 132 may be formed on the mask substrate 110. The phase inversion layer 120, the openings 140, and the phase reinversion layer 132 may be formed by etching the phase conversion material 121 by using a photolithography process. The openings 140 may be formed by entirely etching the phase conversion material 121 in etched areas EA. The phase inversion layer 120 may be formed by partially etching the phase conversion material 121 of the center part CA in a thickness direction from a surface of the phase conversion material 121. The phase reinversion layer 132 may be formed in the center part CA in which the phase conversion material 121 is not etched.

FIG. 8 is a cross-sectional view illustrating a display panel fabricated by a method of fabricating a display panel according to an exemplary embodiment of the present inventive concept.

Referring to FIG. 8, a display panel 200 may include a base substrate 210, a thin film transistor (TFT), a passivation layer 220, and a pixel electrode 230. The pixel electrode 230 may include a micro pattern formed by using the mask for exposure 100 (see FIG. 1 or FIG. 3, for example).

The TFT may control an electric field formed in the display panel 200 by providing a data voltage having image information to the pixel electrode 230. The TFT may control an image formed in the display panel 200. The TFT may be disposed on the base substrate 210 and may include a gate electrode GE, a source electrode SE, and a drain electrode DE.

The TFT may be electrically connected to a gate line (not shown). The gate line may provide a gate signal. The TFT may be electrically connected to a data line (not shown). The data line may provide a data voltage. The TFT may be electrically connected to the pixel electrode 230. The gate electrode GE may be formed on the base substrate 210 by branching from the gate line. A gate dielectric layer GI may be included on the gate electrode GE. The gate dielectric may cover the gate electrode GE. The gate dielectric layer GI may include an organic layer and/or an inorganic layer.

A semiconductor layer AL may be disposed on the gate electrode GE having the gate dielectric layer GI disposed therebetween. The source electrode SE may be branched from the data line and disposed on the gate electrode GE having the semiconductor layer AL disposed therebetween, The drain electrode DE and the source electrode SE may be spaced apart. The drain electrode DE and the source electrode SE may be insulated from each other. The drain electrode DE and the source electrode SE may be disposed on the gate electrode GE having the semiconductor layer AL disposed therebetween.

The passivation layer 220 may cover the TFT. A contact hole CNT may penetrate the passivation layer 220 on the drain electrode DE.

The pixel electrode 230 may receive a data voltage from the TFT and may form an electric filed. The pixel electrode 230 may control an image formed in the display panel 200. The pixel electrode 230 may be included along the contact hole CNT. The pixel electrode 230 may be electrically connected to the drain electrode DE The pixel electrode 230 may include a micro pattern that is composed of branch parts 231 and slit pattern parts 232. The branch parts 231 and the slit pattern parts 232 may be formed in a micro pattern. A pixel electrode material included in the pixel electrode 230 may be, for example, a transparent conductive material, such as indium tin oxide (ITO).

The branch parts 231 and the slit pattern parts 232 may be formed by a photolithography process using the mask for exposure 100. For example, a pattern target layer formed of the pixel electrode material on the passivation layer 220 may be etched to respectively correspond to the shapes of the branch parts 231 and the slit pattern parts 232.

The phase inversion layer 120 (see FIG. 1, for example) having the slit 131 (see FIG. 1, for example) may be formed therein. The openings 140 (see FIG. 1, for example) may be formed during the photolithography process and may be disposed to correspond to areas in which the branch parts 231 and the slit pattern parts 232 are formed. The photoresist layer PR (see FIG. 1, for example) may be provided on the pixel electrode material.

The photoresist layer PR may be developed in areas corresponding to the openings 140. When the pixel electrode material is exposed, the pixel electrode material may be etched. The slit pattern parts 232 may be formed in the corresponding areas.

When the pixel electrode material in an area corresponding to the phase inversion layer 120 of the photoresist layer PR is not exposed, the pixel electrode material might not be etched. As described above, when the photoresist layer PR in the area corresponding to the area, in which the phase inversion layer 120 is formed, is uniformly developed by the destructive interference between the offset light due to the slit 131 and the inversed light due to the phase inversion layer 120, the photoresist layer PR in the corresponding area may have a uniform thickness. The pixel electrode material might not be exposed due to the groove of the side lobes formed in the photoresist layer 120.

When the offset light generated by the slit is used, the slit pattern parts 232 and the branch parts 231 may be finely formed, and the formation of a defective pattern due to the groove of the side lobes may be prevented. A pattern having higher resolution than the resolution limit of a typical exposure apparatus may be formed in the pixel electrode 230.

As described above, the mask for exposure according to exemplary embodiments of the present inventive concept may develop a photoresist in a non-etched area to a uniform thickness. The formation of a defective pattern in the non etched area may be prevented. The reliability of a process of forming a micro pattern may be increased and a resolution limit of an exposure apparatus may be increased, While the present inventive concept has been particularly shown and described with reference to exemplary embodiments thereof, it will be understood by those of ordinary skill in the art that various changes in form and details may be made therein without departing from the spirit and scope of the present inventive concept.

What is claimed is:

1. A mask for etching a pattern target layer, comprising:
a mask substrate;
a phase inversion layer disposed to correspond to a non-etched area of a pattern target layer, wherein the phase inversion layer is configured to generate inverted light by inverting a phase of incident light and to transmit the inverted light to the non-etched area of the pattern target layer; and
an inversion offset part disposed in a center part of the phase inversion layer, wherein the inversion offset part is configured to generate offset light causing destructive interference with the inverted light in the non-etched area and to provide the offset light to the non-etched area.

2. The mask for exposure of claim 1, wherein the inversion offset part includes a slit disposed in the phase inversion layer, and the offset light has a non-inverted phase that is transmitted through the slit.

3. The mask for exposure of claim 1, wherein the inversion offset part includes a phase reinversion layer disposed on the phase inversion layer, and the offset light has a phase that is inverse to a phase of the inverted light that is transmitted through the phase inversion layer.

4. The mask for exposure of claim 3, wherein the phase reinversion layer includes a same material as the phase inversion layer and the phase reinversion layer has a same thickness as the phase inversion layer.

5. The mask for exposure of claim 1, wherein a width of the inversion offset part is in a range of about 0.1 μm to about 1 μm.

6. The mask for exposure of claim 1, wherein when a pitch is defined as a sum of a width of the etched area and a width of the non-etched area, the pitch is in a range of about 2 μm to about 20 μm.

7. The mask for exposure of claim 1, wherein a wavelength of the light transmitted to the mask substrate is in a range of about 300 nm to about 450 nm.

8. The mask for exposure of claim 1, wherein a plurality of inversion offset parts are disposed in the non-etched area.

9. A method of fabricating a mask for exposure for etching a pattern target layer, the method comprising:
providing a phase conversion material configured to shift a phase of light transmitted to a mask substrate;
forming a phase inversion layer on the mask substrate, wherein the phase inversion layer generates inverted light by inverting a phase of the transmitted light to provide the transmitted light to a non-etched area of a pattern target layer by etching the phase conversion material; and
forming an inversion offset part, wherein the inversion offset part generates offset light causing destructive interference with the inverted light in a center part of a non-etched area of the pattern target layer and provides the offset light to a center portion of the non-etched area.

10. The method of claim 9, wherein the forming of the phase inversion layer and the inversion offset part comprises forming a slit that generates the offset light having a non-inverted phase by etching the phase inversion layer on the center part of the non-etched area.

11. The method of claim 9, wherein the forming of the phase inversion layer and the inversion offset part comprises forming a phase reinversion layer that generates the offset light having a phase that is inverse to a phase of the inverted light on the center part of the non-etched area.

12. The method of claim 11, wherein the forming of the phase inversion layer and the inversion offset part comprises etching a portion of the phase conversion material.

13. A method of fabricating a display panel, the method comprising:
forming a base substrate;
forming a thin film transistor on the base substrate:
forming a pixel electrode, electrically connected to the thin film transistor, on the base substrate; and
forming a micro pattern on the pixel electrode using a mask for exposure,
wherein an etched area and a non-etched area, which correspond to the micro pattern, are defined in the pixel electrode, and
the mask for exposure comprises:
a mask substrate;
a phase inversion layer disposed to correspond to the non-etched area, wherein the phase inversion layer is configured to generate inverted light by inverting a phase of incident light and to provide the inverted light to the non-etched area of the pattern target layer; and
an inversion offset part disposed in a center part of the phase inversion layer, wherein the inversion offset part is configured to offset light causing destructive interference with the inverted light in the non-etched area and to provide the offset light to the non-etched area.

14. The method of claim 13, wherein the inversion offset part includes a slit formed in the phase inversion layer, and the offset light has a non-inverted phase that is transmitted through the slit.

15. The method of claim 11, wherein the inversion offset part includes a phase reinversion layer disposed on the phase inversion layer, and the offset light has a phase that is inverse to a phase of the inverted light that is transmitted through the phase inversion layer.

16. A mask for exposure, comprising:
a mask substrate;
a phase inversion layer disposed on the mask substrate, wherein the phase inversion layer is configured to generate inverted light by inverting a phase of incident light and providing the inverted light to the non-etched area of the pattern target layer; and
an inversion offset part disposed on the phase inversion layer, wherein the inversion offset part includes a first slit and a second slit separated from each other by a predetermined distance.

17. The mask for exposure of claim 16, wherein the first slit and the second slit are disposed in a center portion of the inversion offset part.

18. The mask for exposure of claim 16, further comprising openings disposed on opposite ends of the mask substrate.

19. The mask for exposure of claim 16, wherein the first slit and the second slit are disposed in a center portion of the inversion offset part, and openings are disposed on opposite ends of the mask substrate.

20. The mask for exposure of claim 16, wherein the first slit and the second slit are configured to face a center part of a non-etched area of a pattern target layer.
